(19) United States
(12) Patent Application Publication
(10) Pub. No.: US 2025/0166679 A1
(43) Pub. Date: May 22, 2025

(54) SEMICONDUCTOR DEVICE

(71) Applicant: SK hynix Inc., Gyeonggi-do (KR)

(72) Inventors: Jae Hyeong HONG, Gyeonggi-do (KR); Bon Kwang KOO, Gyeonggi-do (KR); Ki Chang GWON, Gyeonggi-do (KR); Chan Keun KWON, Gyeonggi-do (KR); Beom Kyu SEO, Gyeonggi-do (KR); Keun Seon AHN, Gyeonggi-do (KR); Soon Sung AN, Gyeonggi-do (KR); Sung Hwa OK, Gyeonggi-do (KR); Ji Young LEE, Gyeonggi-do (KR); Jun Seo JANG, Gyeonggi-do (KR); Jae Hoon JUNG, Gyeonggi-do (KR); Eun Ji CHOI, Gyeonggi-do (KR)

(21) Appl. No.: 18/625,205

(22) Filed: Apr. 3, 2024

(30) Foreign Application Priority Data
Nov. 20, 2023 (KR) 10-2023-0160312

(51) Int. Cl. G11C 7/22

(52) U.S. Cl. CPC G11C 7/222

(57) ABSTRACT

Disclosed is a memory device including a data pad, at least one merge node, a first data path coupled between the data pad and the at least one merge node and outputting, in a first mode, a first data signal to the at least one merge node based on a data signal, a reference signal and a mode selection signal; a second data path coupled between the data pad and the at least one merge node and outputting, in a second mode, a second data signal to the at least one merge node based on the data signal, the reference signal and the mode selection signal; and a synchronization path coupled to the at least one merge node and outputting, in one of the first and second modes, a corresponding signal of the first and second data signals as a data signal synchronized with at least one data strobe signal.

### CROSS-REFERENCE TO RELATED APPLICATION(S)

This application claims priority under 35 U.S.C. § 119 to Korean Patent Application No. 10-2023-0160312, filed on Nov. 20, 2023, the disclosure of which is incorporated herein by reference in its entirety.

### BACKGROUND

### 1. Field

Various embodiments of the present disclosure relate to a semiconductor design technique, and more particularly, to a semiconductor device including an interface circuit.

### 2. Description of the Related Art

A semiconductor device may receive or output various signals through predetermined operations. For example, a memory device receives data signals and data strobe signals from a memory control device or outputs them to the memory control device.

The semiconductor device includes an interface circuit for inputting and outputting the various signals. The interface circuit is being developed in various ways depending on modes.

### SUMMARY

Various embodiments of the present disclosure are directed to a semiconductor device that supports various interface modes.

In accordance with an embodiment of the present disclosure, a semiconductor device may include: a data pad, at least one merge node, a first data path coupled between the data pad and the at least one merge node and suitable for outputting, in a first mode, a first data signal to the at least one merge node based on a data signal, a reference signal and a mode selection signal; a second data path coupled between the data pad and the at least one merge node and suitable for outputting, in a second mode, a second data signal to the at least one merge node based on the data signal, the reference signal and the mode selection signal; and a synchronization path coupled to the at least one merge node and suitable for outputting, in one of the first and second modes, a corresponding signal of the first and second data signals as a data signal synchronized with at least one data strobe signal.

In accordance with an embodiment of the present disclosure, a semiconductor device may include: a data pad; at least one common node; a common path coupled between the data pad and the at least one common node and suitable for outputting a common data signal to the at least one common node based on a data signal and a reference signal; at least one merge node; a first data path coupled between the at least one common node and the at least one merge node and suitable for outputting, in a first mode, a first data signal to the at least one merge node based on the common data signal and a mode selection signal; a second data path coupled between the at least one common node and the at least one merge node and suitable for outputting, in a second mode, a second data signal to the at least one merge node based on the common data signal and the mode selection signal; and a synchronization path coupled to the at least one merge node and suitable for outputting, in one of the first and second modes, a corresponding signal of the first and second data signals as a data signal synchronized with a data strobe signal.

In accordance with an embodiment of the present disclosure, a semiconductor device may include: a first data path suitable for generating, in a first mode, a first data signal based on a data signal and a reference signal; a second data path suitable for generating, in a second mode, a second data signal based on the data signal and the reference signal; and a synchronization path suitable for outputting, in each of the first and second modes, a selected signal from among the first and second data signals as a data signal synchronized with at least one data strobe signal based on a mode selection signal, the at least one data strobe signal and the first and second data signals.

Other features, aspects, and advantages of the present invention will become apparent from the following detailed description, the drawings, and the claims.

### BRIEF DESCRIPTION OF THE DRAWINGS

FIG. 1 is a block diagram illustrating a semiconductor device in accordance with a first embodiment of the present disclosure.

FIG. 2 is a block diagram illustrating a first data path, second data path, and synchronization path illustrated in FIG. 1.

FIG. 3 is a circuit diagram illustrating a repeater disposed at the end of a second replica circuit included in the first data path illustrated in FIG. 2.

FIG. 4 is a circuit diagram illustrating an input circuit included in the second data path illustrated in FIG. 2.

FIG. 5 is a block diagram illustrating another embodiment of the first data path, second data path, and synchronization path illustrated in FIG. 1.

FIG. 6 is a block diagram illustrating a semiconductor device in accordance with a second embodiment of the present disclosure.

FIG. 7 is a block diagram illustrating a first data path, second data path, and synchronization path illustrated in FIG. 6.

FIG. 8 is a block diagram illustrating a semiconductor device in accordance with a third embodiment of the present disclosure.

FIG. 9 is a block diagram illustrating an example of a first data path, second data path, and synchronization path illustrated in FIG. 8.

FIG. 10 is a circuit diagram illustrating a first selection circuit included in the synchronization path illustrated in FIG. 9.

FIG. 11 is a block diagram illustrating another embodiment of the first data path, second data path, and synchronization path illustrated in FIG. 8.

FIG. 12 is a block diagram illustrating yet another embodiment of the first data path, second data path, and synchronization path illustrated in FIG. 8.

FIG. 13 is a circuit diagram illustrating a first integrated circuit illustrated in FIG. 12.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is referred to as being “connected to” or “coupled to” another element, the element may be directly connected to or coupled to the another element, or electrically connected to or coupled to the another element with one or more elements interposed therebetween. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the present disclosure is not limited thereto, and it will be understood that the components may be formed in plural. In this disclosure, a pair of positive and negative signals may refer to signals complementary to each other such as differentially complementary signals. The positive signal does not have to always have a positive value and may have a negative value as occasion demands. The negative signal does not have to always have a negative value and may have a positive value as occasion demands.

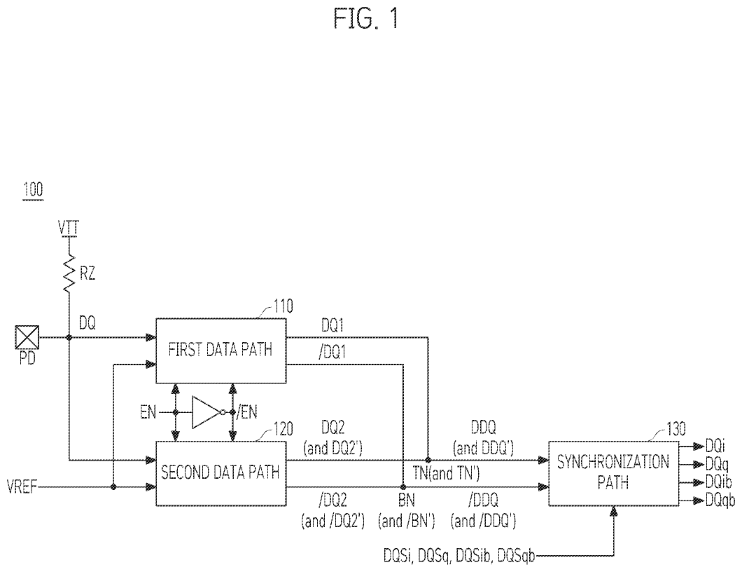

FIG. 1 is a block diagram illustrating a semiconductor device 100 in accordance with a first embodiment of the present disclosure.

Referring to FIG. 1, the semiconductor device 100 may include a data pad PD, a first data path 110, a second data path 120, and a synchronization path 130.

The data pad PD may be coupled to an external device. The data pad PD may receive a data signal DQ outputted from the external device. The data pad PD may be coupled to a supply terminal of a high voltage VTT through a termination resistor RZ.

The first data path 110 may be coupled between the data pad PD and a pair of merge nodes TN and BN. The first data path 110 may be enabled in a first mode on the basis of a mode selection signal EN. For example, the first mode may be a low-speed mode to which a predetermined internal delay time amount is applied. The first data path 110 may output first differential data signals DQ1 and/DQ1 to the pair of merge nodes TN and BN as differential data signals DDQ and/DDQ, respectively, in the first mode on the basis of the data signal DQ, a reference signal VREF and the mode selection signal EN.

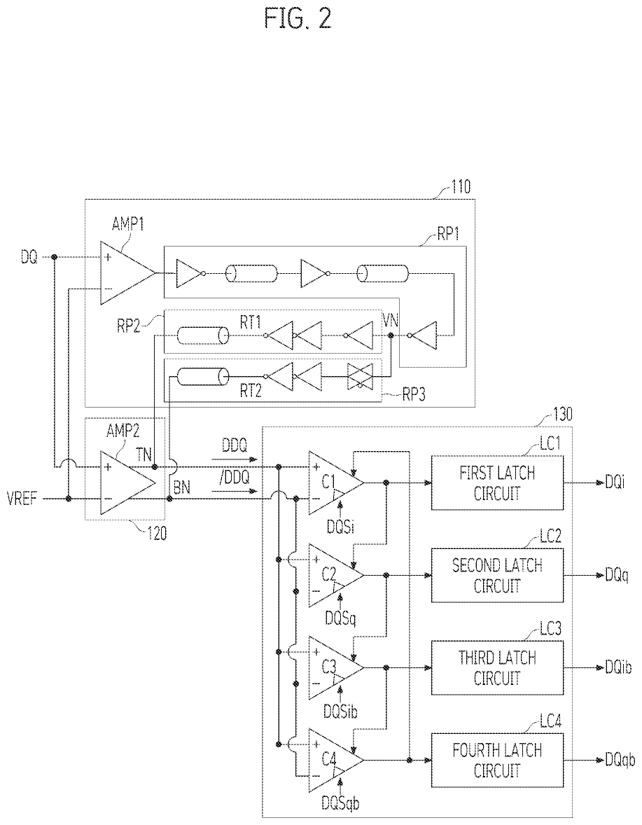

The second data path 120 may be coupled between the data pad PD and the pair of merge nodes TN and BN. The second data path 120 may be enabled in a second mode on the basis of the mode selection signal EN. For example, the second mode may be a high-speed mode to which the internal delay time amount is not applied. According to one example, the second data path 120 may output second differential data signals DQ2 and/DQ2 to the pair of merge nodes TN and BN as the differential data signals DDQ and/DDQ, respectively, in the second mode on the basis of the data signal DQ, the reference signal VREF and the mode selection signal EN (refer to FIG. 2). According to another example, the second data path 120 may output the second differential data signals DQ2 and/DQ2 to a pair of first merge nodes TN and BN as the differential data signals DDQ and/DDQ, respectively, and may output third differential data signals DQ2′ and/DQ2′ to a pair of second merge nodes TN′ and BN′ as differential data signals DDQ′ and/DDQ′, respectively, in the second mode on the basis of the data signal DQ, the reference signal VREF and the mode selection signal EN.

The synchronization path 130 may be coupled to the pair of merge nodes TN and BN. The synchronization path 130 may output the differential data signals DDQ and/DDQ as first to fourth data signals DQi, DQq, Dqib and DQqb synchronized with first to fourth data strobe signals DQSi, DQSq, DQSib and DQSqb in the first mode or the second mode. The first to fourth data strobe signals DQSi, DQSq, DQSib and DQSqb may have different phases. For example, the first and second data strobe signals DQSi and DQSq may have a phase difference of 90 degrees, the second and third data strobe signals DQSq and DQSib may have a phase difference of 90 degrees, and the third and the fourth data strobe signal DQSib and DQSqb may have a phase difference of 90 degrees.

FIG. 2 is a block diagram illustrating the first data path 110, second data path 120, and synchronization path 130 illustrated in FIG. 1.

Referring to FIG. 2, the first data path 110 may include a first input circuit AMP1, a first replica circuit RP1, a second replica circuit RP2, and a third replica circuit RP3.

The first input circuit AMP1 may generate an input data signal on the basis of the data signal DQ and the reference signal VREF. For example, the first input circuit AMP1 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

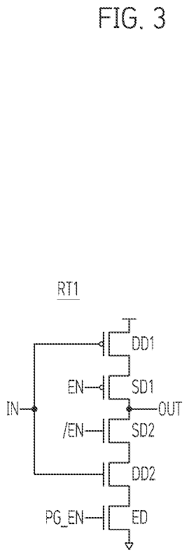

The second replica circuit RP2 may delay the delayed input data signal by a second delay time amount and may output a first positive data signal DQ1 among the first differential data signals DQ1 and/DQ1 to a first merge node TN among the pair of merge nodes TN and BN. For example, the second replica circuit RP2 may include one or more delay lines, for example, an RC line, and one or more repeaters. The one or more delay lines and the one or more repeaters may be coupled in series. Among the one or more repeaters, a second repeater RT1 disposed at the end of the second replica circuit RP2, that is, disposed closest to the first merge node TN, may be enabled in response to the mode selection signal EN (refer to FIG. 3).

The third replica circuit RP3 may delay the delayed input data signal by the second delay time amount and may output a first negative data signal/DQ1 among the first differential data signals DQ1 and/DQ1 to a second merge node BN among the pair of merge nodes TN and BN. For example, the third replica circuit RP3 may include one or more delay lines, for example, an RC line, and one or more repeaters. The one or more delay lines and the one or more repeaters may be coupled in series. Among the one or more repeaters, a third repeater RT2 disposed at the end of the third replica circuit RP3, that is, disposed closest to the second merge node BN, may be designed in the same manner as the second repeater RT1, and may be enabled in response to the mode selection signal EN (refer to FIG. 3).

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 100 to a point in time when the first to fourth data strobe signals DQSi, DQSq, DQSib and DQSqb based on the data strobe signal are inputted to the synchronization path 130.

The second data path 120 may include a second input circuit AMP2.

The second input circuit AMP2 may output the second differential data signals DQ2 and/DQ2 to the first merge node TN and the second merge node BN as the differential data signals DDQ and/DDQ, respectively, on the basis of the data signal DQ and the reference signal VREF. For example, the second input circuit AMP2 may include an amplifier.

The synchronization path 130 may include first to fourth comparison circuits C₁ to C₄ and first to fourth latch circuits LC1 to LC4.

The first comparison circuit C1 may be synchronized with the first data strobe signal DQSi and may perform a comparison operation for a first time amount. The first time amount may be related to a phase of the first data strobe signal DQSi. For example, the first time amount may correspond to one cycle of the first data strobe signal DQSi on the basis of a rising edge of the first data strobe signal DQSi. The first comparison circuit C1 may compare the positive data signal DDQ outputted through the first merge node TN with the negative data signal/DDQ outputted through the second merge node BN in the first mode and may generate and latch a first comparison data signal corresponding to a result of the comparing. The first comparison circuit C1 may compare the positive data signal DDQ outputted through the first merge node TN with the negative data signal/DDQ outputted through the second merge node BN in the second mode and may generate and latch the first comparison data signal corresponding to a result of the comparing.

The second comparison circuit C2 may be synchronized with the second data strobe signal DQSq and may perform the comparison operation for a second time amount. The second time amount may be related to a phase of the second data strobe signal DQSq. For example, the second time amount may correspond to one cycle of the second data strobe signal DQSq on the basis of a rising edge of the second data strobe signal DQSq. The second comparison circuit C2 may compare the positive data signal DDQ outputted through the first merge node TN with the negative data signal/DDQ outputted through the second merge node BN in the first mode and may generate and latch a second comparison data signal corresponding to a result of the comparing. The second comparison circuit C2 may compare the positive data signal DDQ outputted through the first merge node TN with the negative data signal/DDQ outputted through the second merge node BN in the second mode and may generate and latch the second comparison data signal corresponding to a result of the comparing.

The third comparison circuit C3 may be synchronized with the third data strobe signal DQSib and may perform the comparison operation for a third time amount. The third time amount may be related to a phase of the third data strobe signal DQSib. For example, the third time amount may correspond to one cycle of the third data strobe signal DQSib on the basis of a rising edge of the third data strobe signal DQSib. The third comparison circuit C3 may compare the positive data signal DDQ outputted through the first merge node TN with the negative data signal/DDQ outputted through the second merge node BN in the first mode and may generate and latch a third comparison data signal corresponding to a result of the comparing. The third comparison circuit C3 may compare the positive data signal DDQ outputted through the first merge node TN with the negative data signal/DDQ outputted through the second merge node BN in the second mode and may generate and latch the third comparison data signal corresponding to a result of the comparing.

The fourth comparison circuit C4 may be synchronized with the fourth data strobe signal DQSqb and may perform the comparison operation for a fourth time amount. The fourth time amount may be related to a phase of the fourth data strobe signal DQSqb. For example, the fourth time amount may correspond to one cycle of the fourth data strobe signal DQSqb on the basis of a rising edge of the fourth data strobe signal DQSqb. The fourth comparison circuit C4 may compare the positive data signal DDQ outputted through the first merge node TN with the negative data signal/DDQ outputted through the second merge node BN in the first mode and may generate and latch a fourth comparison data signal corresponding to a result of the comparing. The fourth comparison circuit C4 may compare the positive data signal DDQ outputted through the first merge node TN with the negative data signal/DDQ outputted through the second merge node BN in the second mode and may generate and latch the fourth comparison data signal corresponding to a result of the comparing.

Each of the first to fourth comparison circuits C1 to C4 may receive the comparison data signal outputted from the comparison circuit C1 to C4 adjacent thereto. The first comparison circuit C1 may receive the fourth comparison data signal outputted from the fourth comparison circuit C4. This operation is known as a decision feedback equalization (DFE) operation.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

FIG. 3 is a circuit diagram illustrating the second repeater RT1 disposed at the end of the second replica circuit RP2 among the one or more repeaters included in the second replica circuit RP2 illustrated in FIG. 2.

Referring to FIG. 3, the second repeater RT1 may include a first pull-up driver DD1, a first selection driver SD1, a second selection driver SD2, a first pull-down driver DD2, and a power gating element ED.

The first pull-up driver DD1 may be coupled between a supply terminal of a first voltage and a first supply node. The first pull-up driver DD1 may pull-up drive the first supply node with the first voltage on the basis of a first driving data signal IN corresponding to the delayed input data signal.

The first selection driver SD1 may be coupled between the first supply node and a first output node. The first selection driver SD1 may selectively couple the first supply node to the first output node on the basis of the mode selection signal EN. An output signal corresponding to the first positive data signal DQ1 may be generated through the first output node.

The second selection driver SD2 may be coupled between the first output node and a second supply node. The second selection driver SD2 may selectively couple the first output node to the second supply node on the basis of an inversion signal/EN of the mode selection signal EN.

The first pull-down driver DD2 may be coupled between the second supply node and a supply terminal of a second voltage. The first pull-down driver DD2 may pull-down drive the second supply node with the second voltage on the basis of the first driving data signal IN.

The power gating element ED may enable the second repeater RT1 on the basis of an enable signal PG_EN. For example, the enable signal PG_EN may be a write enable signal.

Since the third repeater RT2 disposed at the end of the third replica circuit RP3 among the one or more repeaters included in the third replica circuit RP3 illustrated in FIG. 2 may be designed in the same manner as the second repeater RT1 illustrated in FIG. 3, a description of the third repeater RT2 is omitted.

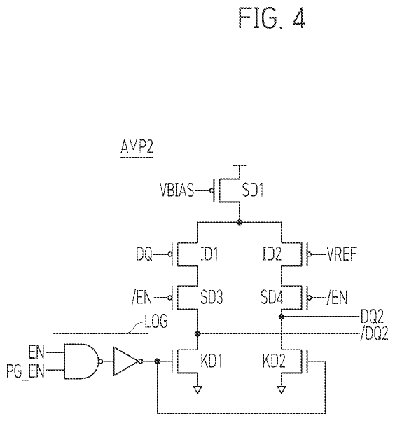

FIG. 4 is a circuit diagram illustrating the second input circuit AMP2 included in the second data path 120 illustrated in FIG. 2.

Referring to FIG. 4, the second input circuit AMP2 may include a source driver SD1, a first input driver ID1, a third selection driver SD3, a second input driver ID2, a fourth selection driver SD4, a first sink driver KD1, a second sink driver KD2, and a logic circuit LOG.

The source driver SD1 may be coupled between the supply terminal of the first voltage and a common node CN. The source driver SD1 may receive a bias voltage VBIAS. The source driver SD1 may supply the first voltage to the common node CN on the basis of the bias voltage VBIAS.

The first input driver ID1 may be coupled between the common node CN and a first node. The first input driver ID1 may receive the data signal DQ.

The third selection driver SD3 may be coupled between the first node and the second merge node BN. The third selection driver SD3 may receive the inversion signal/EN of the mode selection signal EN.

The second input driver ID2 may be coupled between the common node CN and a second node. The second input driver ID2 may receive the reference signal VREF.

The fourth selection driver SD4 may be coupled between the second node and the first merge node TN. The fourth selection driver SD4 may receive the inversion signal/EN of the mode selection signal EN.

The first sink driver KD1 may be coupled between the second merge node BN and the supply terminal of the second voltage. The first sink driver KD1 may receive a control signal.

The second sink driver KD2 may be coupled between the first merge node TN and the supply terminal of the second voltage. The second sink driver KD2 may receive the control signal.

The logic circuit LOG may generate the control signal on the basis of the mode selection signal EN and the enable signal PG_EN. For example, the logic circuit LOG may include a NAND gate and an inverter. The NAND gate may perform a NOR operation on the mode selection signal EN and the enable signal PG_EN. The inverter may invert an output signal of the NAND gate and may generate the control signal.

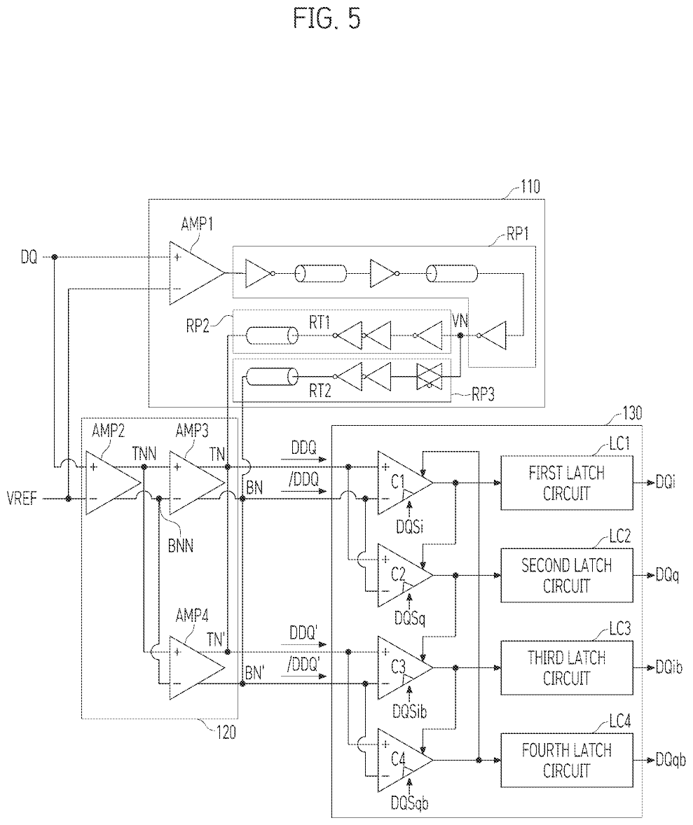

FIG. 5 is a block diagram illustrating another embodiment of the first data path 110, second data path 120, and synchronization path 130 illustrated in FIG. 1.

Referring to FIG. 5, the first data path 110 may include a first input circuit AMP1, a first replica circuit RP1, a second replica circuit RP2, and a third replica circuit RP3.

The first input circuit AMP1 may generate an input data signal on the basis of the data signal DQ and the reference signal VREF. For example, the first input circuit AMP1 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

The second replica circuit RP2 may delay the delayed input data signal by a second delay time amount and may output a first positive data signal DQ1 among the first differential data signals DQ1 and/DQ1 to a third merge node TN among the pair of first merge nodes TN and BN and a fifth merge node TN′ among the pair of second merge nodes TN′ and BN′. For example, the second replica circuit RP2 may include one or more delay lines, for example, an RC line, and one or more repeaters. The one or more delay lines and the one or more repeaters may be coupled in series. Among the one or more repeaters, a second repeater RT1 disposed at the end of the second replica circuit RP2, that is, disposed closest to the third merge node TN, may be enabled in response to the mode selection signal EN (refer to FIG. 3).

The third replica circuit RP3 may delay the delayed input data signal by the second delay time amount and may output a first negative data signal/DQ1 among the first differential data signals DQ1 and/DQ1 to a fourth merge node BN among the pair of first merge nodes TN and BN and a sixth merge node BN′ among the pair of the second merge modes TN′ and BN′. For example, the third replica circuit RP3 may include one or more delay lines, for example, an RC line, and one or more repeaters. The one or more delay lines and the one or more repeaters may be coupled in series. Among the one or more repeaters, a third repeater RT2 disposed at the end of the third replica circuit RP3, that is, disposed closest to the fourth merge node BN, may be enabled in response to the mode selection signal EN (refer to FIG. 3).

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 100 to a point in time when the first to fourth data strobe signals DQSi, DQSq, DQSib and DQSqb based on the data strobe signal are inputted to the synchronization path 130.

The second data path 120 may include second to fourth input circuits AMP2, AMP3, and AMP4.

The second input circuit AMP2 may output differential data signals to a pair of branch nodes TNN and BNN on the basis of the data signal DQ and the reference signal VREF. For example, the second input circuit AMP2 may include an amplifier.

The third input circuit AMP3 may output the second differential data signals DQ2 and/DQ2 to the pair of first merge nodes TN and BN as the differential data signals DDQ and/DDQ on the basis of the differential data signals outputted from the second input circuit AMP2. For example, the third input circuit AMP3 may include an amplifier.

The fourth input circuit AMP3 may output the third differential data signals DQ2′ and/DQ2′ to the pair of second merge nodes TN′ and BN′ as the differential data signals DDQ′ and/DDQ′ on the basis of the differential data signals outputted from the second input circuit AMP2. For example, the fourth input circuit AMP4 may include an amplifier.

Each of the second to fourth input circuits AMP2, AMP3, and AMP4 may be designed in the same manner as or differently from the second input circuit AMP2 illustrated in FIG. 4.

The synchronization path 130 may include first to fourth comparison circuits C₁ to C₄ and first to fourth latch circuits LC1 to LC4.

The first comparison circuit C1 may be synchronized with the first data strobe signal DQSi and may perform a comparison operation for a first time amount. The first time amount may be related to a phase of the first data strobe signal DQSi. For example, the first time amount may correspond to one cycle of the first data strobe signal DQSi on the basis of a rising edge of the first data strobe signal DQSi. The first comparison circuit C1 may compare a third positive data signal DDQ outputted through the first merge node TN with a third negative data signal/DDQ outputted through the second merge node BN in the first mode and may generate and latch a first comparison data signal corresponding to a result of the comparing. The first comparison circuit C1 may compare the third positive data signal DDQ outputted through the first merge node TN with the third negative data signal/DDQ outputted through the second merge node BN in the second mode and may generate and latch the first comparison data signal corresponding to a result of the comparing.

The second comparison circuit C2 may be synchronized with the second data strobe signal DQSq and may perform the comparison operation for a second time amount. The second time amount may be related to a phase of the second data strobe signal DQSq. For example, the second time amount may correspond to one cycle of the second data strobe signal DQSq on the basis of a rising edge of the second data strobe signal DQSq. The second comparison circuit C2 may compare the third positive data signal DDQ outputted through the first merge node TN with the third negative data signal/DDQ outputted through the second merge node BN in the first mode and may generate and latch a second comparison data signal corresponding to a result of the comparing. The second comparison circuit C2 may compare the third positive data signal DDQ outputted through the first merge node TN with the third negative data signal/DDQ outputted through the second merge node BN in the second mode and may generate and latch the second comparison data signal corresponding to a result of the comparing.

The third comparison circuit C3 may be synchronized with the third data strobe signal DQSib and may perform the comparison operation for a third time amount. The third time amount may be related to a phase of the third data strobe signal DQSib. For example, the third time amount may correspond to one cycle of the third data strobe signal DQSib on the basis of a rising edge of the third data strobe signal DQSib. The third comparison circuit C3 may compare a fourth positive data signal DDQ′ outputted through the third merge node TN′ with a fourth negative data signal/DDQ′ outputted through the fourth merge node BN′ in the first mode and may generate and latch a third comparison data signal corresponding to a result of the comparing. The third comparison circuit C3 may compare the fourth positive data signal DDQ′ outputted through the third merge node TN′ with the fourth negative data signal/DDQ′ outputted through the fourth merge node BN′ in the second mode and may generate and latch the third comparison data signal corresponding to a result of the comparing.

The fourth comparison circuit C4 may be synchronized with the fourth data strobe signal DQSqb and may perform the comparison operation for a fourth time amount. The fourth time amount may be related to a phase of the fourth data strobe signal DQSqb. For example, the fourth time amount may correspond to one cycle of the fourth data strobe signal DQSqb on the basis of a rising edge of the fourth data strobe signal DQSqb. The fourth comparison circuit C4 may compare the fourth positive data signal DDQ′ outputted through the third merge node TN′ with the fourth negative data signal/DDQ′ outputted through the fourth merge node BN′ in the first mode and may generate and latch a fourth comparison data signal corresponding to a result of the comparing. The fourth comparison circuit C4 may compare the fourth positive data signal DDQ′ outputted through the third merge node TN′ with the fourth negative data signal/DDQ′ outputted through the fourth merge node BN′ in the second mode and may generate and latch the fourth comparison data signal corresponding to a result of the comparing.

Each of the first to fourth comparison circuits C1 to C4 may receive the comparison data signal outputted from the comparison circuit C1 to C4 adjacent thereto. The first comparison circuit C1 may receive the fourth comparison data signal outputted from the fourth comparison circuit C4. This operation is known as a decision feedback equalization (DFE) operation.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

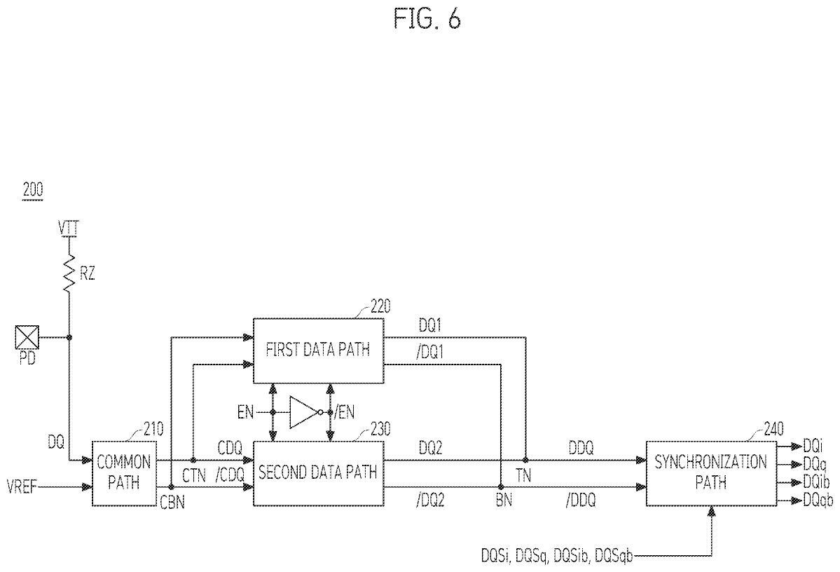

FIG. 6 is a block diagram illustrating a semiconductor device 200 in accordance with a second embodiment of the present disclosure.

Referring to FIG. 6, the semiconductor device 200 may include a data pad PD, a common path 210, a first data path 220, a second data path 230, and a synchronization path 240.

The data pad PD may be coupled to an external device. The data pad PD may receive a data signal DQ outputted from the external device. The data pad PD may be coupled to a supply terminal of a high voltage VTT through a termination resistor RZ.

The common path 210 may be coupled between the data pad PD and a pair of common nodes CTN and CBN. The common path 210 may output differential common data signals CDQ and/CDQ to the pair of common nodes CTN and BTN, respectively, on the basis of the data signal DQ and a reference signal VREF.

The first data path 220 may be coupled between the pair of common nodes CTN and BTN and a pair of merge nodes TN and BN. The first data path 220 may be enabled in a first mode on the basis of a mode selection signal EN. For example, the first mode may be a low-speed mode to which a predetermined internal delay time amount is applied. The first data path 220 may output first differential data signals DQ1 and/DQ1 to the pair of merge nodes TN and BN as differential data signals DDQ and/DDQ, respectively, in the first mode on the basis of the differential common data signals CDQ and/CDQ and the mode selection signal EN.

The second data path 230 may be coupled between the pair of common nodes CTN and BTN and the pair of merge nodes TN and BN. The second data path 230 may be enabled in a second mode on the basis of the mode selection signal EN. For example, the second mode may be a high-speed mode to which the internal delay time amount is not applied. The second data path 230 may output second differential data signals DQ2 and/DQ2 to the pair of merge nodes TN and BN as the differential data signals DDQ and/DDQ, respectively, in the second mode on the basis of the differential common data signals CDQ and/CDQ and the mode selection signal EN.

The synchronization path 240 may be coupled to the pair of merge nodes TN and BN. The synchronization path 240 may output the differential data signals DDQ and/DDQ as first to fourth data signals DQi, DQq, Dqib and DQqb synchronized with first to fourth data strobe signals DQSi, DQSq, DQSib and DQSqb in the first mode or the second mode. The first to fourth data strobe signals DQSi, DQSq, DQSib and DQSqb may have different phases. For example, the first and second data strobe signals DQSi and DQSq may have a phase difference of 90 degrees, the second and third data strobe signals DQSq and DQSib may have a phase difference of 90 degrees, and the third and the fourth data strobe signal DQSib and DQSqb may have a phase difference of 90 degrees.

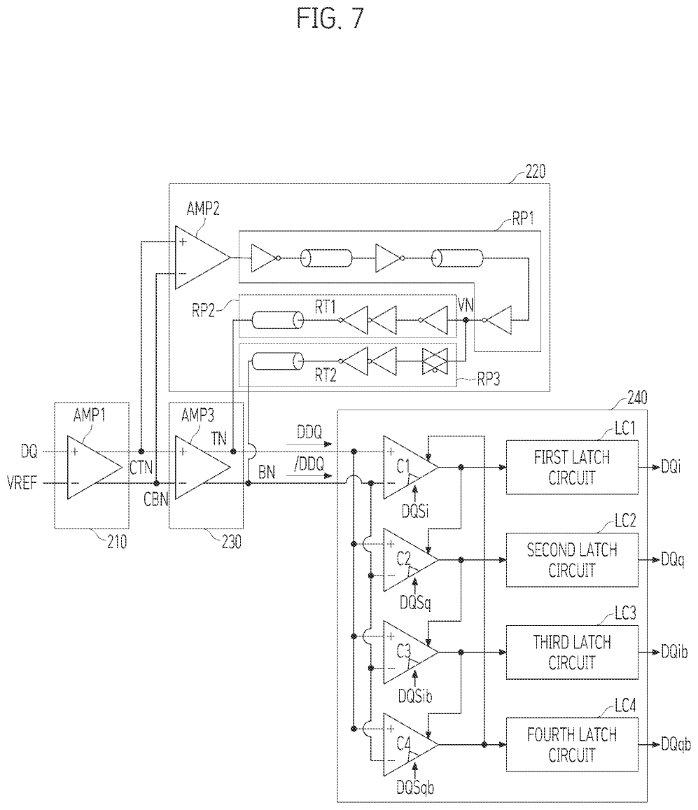

FIG. 7 is a block diagram illustrating the common path 210, first data path 220, second data path 230, and synchronization path 240 illustrated in FIG. 6.

Referring to FIG. 7, the common path 210 may include a first input circuit AMP1.

The first input circuit AMP1 may output the differential common data signals CDQ and/CDQ to the pair of common nodes CTN and BTN on the basis of the data signal DQ and the reference signal VREF. For example, the first input circuit AMP1 may include an amplifier.

The first data path 220 may include a second input circuit AMP2, a first replica circuit RP1, a second replica circuit RP2, and a third replica circuit RP3.

The second input circuit AMP2 may generate an input data signal on the basis of the differential common data signals CDQ and/CDQ. For example, the second input circuit AMP2 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

The second replica circuit RP2 may delay the delayed input data signal by a second delay time amount and may output a first positive data signal DQ1 among the first differential data signals DQ1 and/DQ1 to a first merge node TN among the pair of merge nodes TN and BN. For example, the second replica circuit RP2 may include one or more delay lines, for example, an RC line, and one or more repeaters. The one or more delay lines and the one or more repeaters may be coupled in series. Among the one or more repeaters, a second repeater RT1 disposed at the end of the second replica circuit RP2, that is, disposed closest to the first merge node TN, may be enabled in response to the mode selection signal EN (refer to FIG. 3).

The third replica circuit RP3 may delay the delayed input data signal by the second delay time amount and may output a first negative data signal/DQ1 among the first differential data signals DQ1 and/DQ1 to a second merge node BN among the pair of merge nodes TN and BN. For example, the third replica circuit RP3 may include one or more delay lines, for example, an RC line, and one or more repeaters. The one or more delay lines and the one or more repeaters may be coupled in series. Among the one or more repeaters, a third repeater RT2 disposed at the end of the third replica circuit RP3, that is, disposed closest to the second merge node BN, may be enabled in response to the mode selection signal EN (refer to FIG. 3).

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 200 to a point in time when the first to fourth data strobe signals DQSi, DQSq, DQSib and DQSqb based on the data strobe signal are inputted to the synchronization path 240.

The second data path 230 may include a third input circuit AMP3.

The third input circuit AMP3 may output the second differential data signals DQ2 and/DQ2 to the pair of merge nodes TN and BN as the differential data signals DDQ and/DDQ, respectively, on the basis of the differential common data signals CDQ and/CDQ. For example, the third input circuit AMP3 may include an amplifier.

The synchronization path 240 may include first to fourth comparison circuits C₁ to C₄ and first to fourth latch circuits LC1 to LC4. The first comparison circuit C1 may be synchronized with the first data strobe signal DQSi and may perform a comparison operation for a first time amount. The first time amount may be related to a phase of the first data strobe signal DQSi. For example, the first time amount may correspond to one cycle of the first data strobe signal DQSi on the basis of a rising edge of the first data strobe signal DQSi. The first comparison circuit C1 may compare a positive data signal DDQ outputted through the first merge node TN with a negative data signal/DDQ outputted through the second merge node BN in the first mode and may generate and latch a first comparison data signal corresponding to a result of the comparing. The first comparison circuit C1 may compare the positive data signal DDQ outputted through the first merge node TN with the negative data signal/DDQ outputted through the second merge node BN in the second mode and may generate and latch the first comparison data signal corresponding to a result of the comparing.

The second comparison circuit C2 may be synchronized with the second data strobe signal DQSq and may perform the comparison operation for a second time amount. The second time amount may be related to a phase of the second data strobe signal DQSq. For example, the second time amount may correspond to one cycle of the second data strobe signal DQSq on the basis of a rising edge of the second data strobe signal DQSq. The second comparison circuit C2 may compare the positive data signal DDQ outputted through the first merge node TN with the negative data signal/DDQ outputted through the second merge node BN in the first mode and may generate and latch a second comparison data signal corresponding to a result of the comparing. The second comparison circuit C2 may compare the positive data signal DDQ outputted through the first merge node TN with the negative data signal/DDQ outputted through the second merge node BN in the second mode and may generate and latch the second comparison data signal corresponding to a result of the comparing.

The third comparison circuit C3 may be synchronized with the third data strobe signal DQSib and may perform the comparison operation for a third time amount. The third time amount may be related to a phase of the third data strobe signal DQSib. For example, the third time amount may correspond to one cycle of the third data strobe signal DQSib on the basis of a rising edge of the third data strobe signal DQSib. The third comparison circuit C3 may compare the positive data signal DDQ outputted through the first merge node TN with the negative data signal/DDQ outputted through the second merge node BN in the first mode and may generate and latch a third comparison data signal corresponding to a result of the comparing. The third comparison circuit C3 may compare the positive data signal DDQ outputted through the first merge node TN with the negative data signal/DDQ outputted through the second merge node BN in the second mode and may generate and latch the third comparison data signal corresponding to a result of the comparing.

The fourth comparison circuit C4 may be synchronized with the fourth data strobe signal DQSqb and may perform the comparison operation for a fourth time amount. The fourth time amount may be related to a phase of the fourth data strobe signal DQSqb. For example, the fourth time amount may correspond to one cycle of the fourth data strobe signal DQSqb on the basis of a rising edge of the fourth data strobe signal DQSqb. The fourth comparison circuit C4 may compare the positive data signal DDQ outputted through the first merge node TN with the negative data signal/DDQ outputted through the second merge node BN in the first mode and may generate and latch a fourth comparison data signal corresponding to a result of the comparing. The fourth comparison circuit C4 may compare the positive data signal DDQ outputted through the first merge node TN with the negative data signal/DDQ outputted through the second merge node BN in the second mode and may generate and latch the fourth comparison data signal corresponding to a result of the comparing.

Each of the first to fourth comparison circuits C1 to C4 may receive the comparison data signal outputted from the comparison circuit C1 to C4 adjacent thereto. The first comparison circuit C1 may receive the fourth comparison data signal outputted from the fourth comparison circuit C4. This operation is known as a decision feedback equalization (DFE) operation.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

In an embodiment, it is described that the second data path 230 includes the third input circuit AMP3, but the embodiment is not necessarily limited thereto, and the second data path 230 may be designed in the same manner as the second data path 120 illustrated in FIG. 5. Accordingly, a coupling structure between the second data path 230 and the synchronization path 240 may be designed in the same manner as a coupling structure between the second data path 120 and the synchronization path 130 illustrated in FIG. 5.

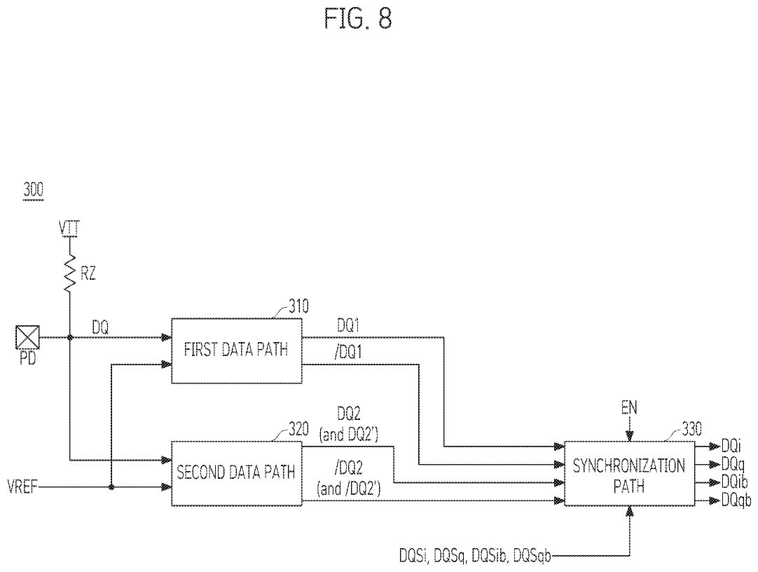

FIG. 8 is a block diagram illustrating a semiconductor device 300 in accordance with a third embodiment of the present disclosure.

Referring to FIG. 8, the semiconductor device 300 may include a data pad PD, a first data path 310, a second data path 320, and a synchronization path 330.

The data pad PD may be coupled to an external device. The data pad PD may receive a data signal DQ outputted from the external device. The data pad PD may be coupled to a supply terminal of a high voltage VTT through a termination resistor RZ.

The first data path 310 may be coupled between the data pad PD and the synchronization path 330. The first data path 310 may generate first differential data signals DQ1 and/DQ1 in a first mode on the basis of the data signal DQ and a reference signal VREF. For example, the first mode may be a low-speed mode to which a predetermined internal delay time amount is applied.

The second data path 320 may be coupled between the data pad PD and the synchronization path 330. The second data path 320 may generate second differential data signals DQ2 and/DQ2 in a second mode on the basis of the data signal DQ and the reference signal VREF. For example, the second mode may be a high-speed mode to which the internal delay time amount is not applied.

Although not illustrated in the drawing, the first data path 310 may be enabled and the second data path 320 may be disabled in the first mode, and the first data path 310 may be disabled and the second data path 320 may be enabled in the second mode.

The synchronization path 330 may output differential data signals selected from among the first differential data signals DQ1 and/DQ1 and the second differential data signals DQ2 and/DQ2 as first to fourth data signals DQi, DQq, DQib and DQqb synchronized with first to fourth data strobe signals DQSi, DQSq, DQSib and DQSqb in the first and second modes on the basis of a mode selection signal EN, the first to fourth data strobe signals DQSi, DQSq, DQSib and DQSqb, the first differential data signals DQ1 and/DQ1, and the second differential data signals DQ2 and/DQ2. The first to fourth data strobe signals DQSi, DQSq, DQSib and DQSqb may have different phases. For example, the first and second data strobe signals DQSi and DQSq may have a phase difference of 90 degrees, the second and third data strobe signals DQSq and DQSib may have a phase difference of 90 degrees, and the third and the fourth data strobe signal DQSib and DQSqb may have a phase difference of 90 degrees.

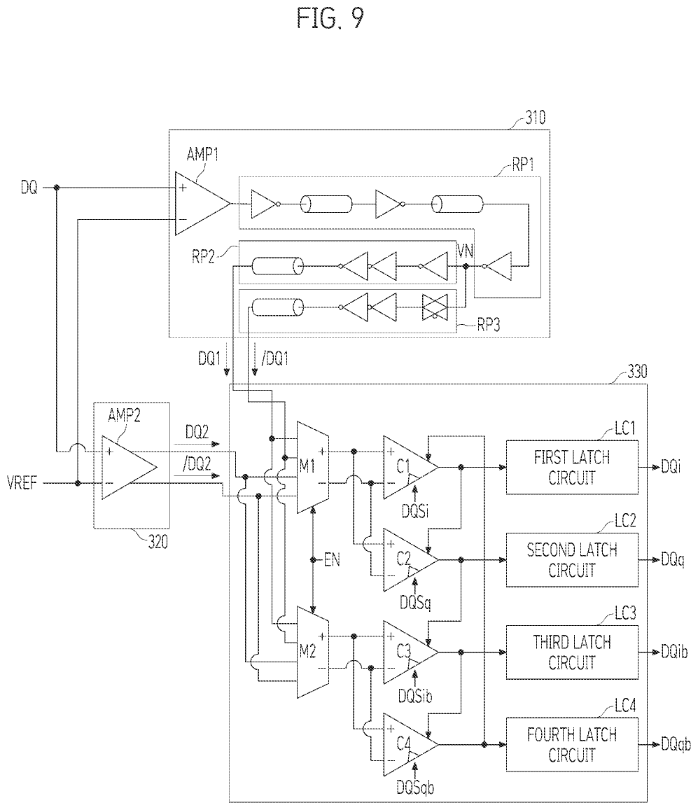

FIG. 9 is a block diagram illustrating the first data path 310, second data path 320, and synchronization path 330 illustrated in FIG. 8.

Referring to FIG. 9, the first data path 310 may include a first input circuit AMP1, a first replica circuit RP1, a second replica circuit RP2, and a third replica circuit RP3.

The first input circuit AMP1 may generate an input data signal on the basis of the data signal DQ and the reference signal VREF. For example, the first input circuit AMP1 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

The second replica circuit RP2 may delay the delayed input data signal by a second delay time amount and may generate a first positive data signal DQ1 among the first differential data signals DQ1 and/DQ1. For example, the second replica circuit RP2 may include one or more delay lines, for example, an RC line, and one or more repeaters. The one or more delay lines and the one or more repeaters may be coupled in series.

The third replica circuit RP3 may delay the delayed input data signal by the second delay time amount and may generate a first negative data signal/DQ1 among the first differential data signals DQ1 and/DQ1. For example, the third replica circuit RP3 may include one or more delay lines, for example, an RC line, and one or more repeaters. The one or more delay lines and the one or more repeaters may be coupled in series.

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 300 to a point in time when the first to fourth data strobe signals DQSi, DQSq, DQSib and DQSqb based on the data strobe signal are inputted to the synchronization path 330.

The second data path 320 may include a second input circuit AMP2.

The second input circuit AMP2 may generate the second differential data signals DQ2 and/DQ2 on the basis of the data signal DQ and the reference signal VREF. For example, the second input circuit AMP2 may include an amplifier. Since the second input circuit AMP2 may be designed in the same manner as the second input circuit AMP2 illustrated in FIG. 4, a detailed description of the second input circuit AMP2 is omitted.

The synchronization path 330 may include first and second selection circuit M1 and M2, first to fourth comparison circuits C1 to C4, and first to fourth latch circuits LC1 to LC4.

The first selection circuit M1 may generate the first differential data signals DQ1 and/DQ1 or the second differential data signals DQ2 and/DQ2 as first differential selection data signals on the basis of the mode selection signal EN.

The second selection circuit M2 may generate the first differential data signals DQ1 and/DQ1 or the second differential data signals DQ2 and/DQ2 as second differential selection data signals on the basis of the mode selection signal EN.

The first comparison circuit C1 may be synchronized with the first data strobe signal DQSi and may perform a comparison operation for a first time amount. The first time amount may be related to a phase of the first data strobe signal DQSi. For example, the first time amount may correspond to one cycle of the first data strobe signal DQSi on the basis of a rising edge of the first data strobe signal DQSi. The first comparison circuit C1 may compare the first differential selection data signals with one another in the first mode and may generate and latch a first comparison data signal corresponding to a result of the comparing. The first comparison circuit C1 may compare the first differential selection data signals with one another in the second mode and may generate and latch the first comparison data signal corresponding to a result of the comparing.

The second comparison circuit C2 may be synchronized with the second data strobe signal DQSq and may perform the comparison operation for a second time amount. The second time amount may be related to a phase of the second data strobe signal DQSq. For example, the second time amount may correspond to one cycle of the second data strobe signal DQSq on the basis of a rising edge of the second data strobe signal DQSq. The second comparison circuit C2 may compare the first differential selection data signals with one another in the first mode and may generate and latch a second comparison data signal corresponding to a result of the comparing. The second comparison circuit C2 may compare the first differential selection data signals with one another in the second mode and may generate and latch the second comparison data signal corresponding to a result of the comparing.

The third comparison circuit C3 may be synchronized with the third data strobe signal DQSib and may perform the comparison operation for a third time amount. The third time amount may be related to a phase of the third data strobe signal DQSib. For example, the third time amount may correspond to one cycle of the third data strobe signal DQSib on the basis of a rising edge of the third data strobe signal DQSib. The third comparison circuit C3 may compare the second differential selection data signals with one another in the first mode and may generate and latch a third comparison data signal corresponding to a result of the comparing. The third comparison circuit C3 may compare the second differential selection data signals with one another in the second mode and may generate and latch the third comparison data signal corresponding to a result of the comparing.

The fourth comparison circuit C4 may be synchronized with the fourth data strobe signal DQSqb and may perform the comparison operation for a fourth time amount. The fourth time amount may be related to a phase of the fourth data strobe signal DQSqb. For example, the fourth time amount may correspond to one cycle of the fourth data strobe signal DQSqb on the basis of a rising edge of the fourth data strobe signal DQSqb. The fourth comparison circuit C4 may compare the second differential selection data signals with one another in the first mode and may generate and latch a fourth comparison data signal corresponding to a result of the comparing. The fourth comparison circuit C4 may compare the second differential selection data signals with one another in the second mode and may generate and latch the fourth comparison data signal corresponding to a result of the comparing.

Each of the first to fourth comparison circuits C₁ to C₄ may receive the comparison data signal outputted from the comparison circuit C₁ to C₄ adjacent thereto. The first comparison circuit C1 may receive the fourth comparison data signal outputted from the fourth comparison circuit C4. This operation is known as a decision feedback equalization (DFE) operation.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

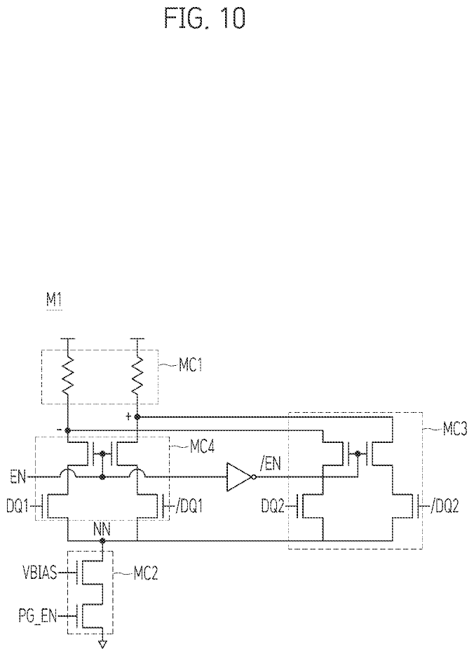

FIG. 10 is a circuit diagram illustrating the first selection circuit M1 included in the synchronization path 330 illustrated in FIG. 9.

Referring to FIG. 10, the first selection circuit M1 may include a source unit MC1, a sink unit MC2, a first selection unit MC3, and a second selection unit MC4.

The source unit MC1 may be coupled between a supply terminal of a first voltage and a pair of output terminals (+, −). For example, the source unit MC1 may include first and second resistors. The first resistor may be coupled between the supply terminal of the first voltage and a first output terminal (+). The second resistor may be coupled between the supply terminal of the first voltage and a second output terminal (−).

The sink unit MC2 may be coupled between a coupling node NN and a supply terminal of a second voltage. For example, the sink unit MC2 may include first and second transistors coupled in series. The first transistor may be coupled between the coupling node NN and a sink node and may receive a bias voltage VBIAS to a gate terminal thereof. The second transistor may be coupled between the sink node and the supply terminal of the second voltage and may receive an enable signal PG_EN to a gate terminal thereof.

The first selection unit MC3 may be enabled in the first mode and disabled in the second mode on the basis of an inversion signal/EN of the mode selection signal EN.

The second selection unit MC4 may be enabled in the second mode and disabled in the first mode on the basis of the mode selection signal EN.

Since the second selection circuit M2 included in the synchronization path 330 illustrated in FIG. 9 may be designed in the same manner as the first selection circuit M1 illustrated in FIG. 10, a detailed description of the second selection circuit M2 is omitted.

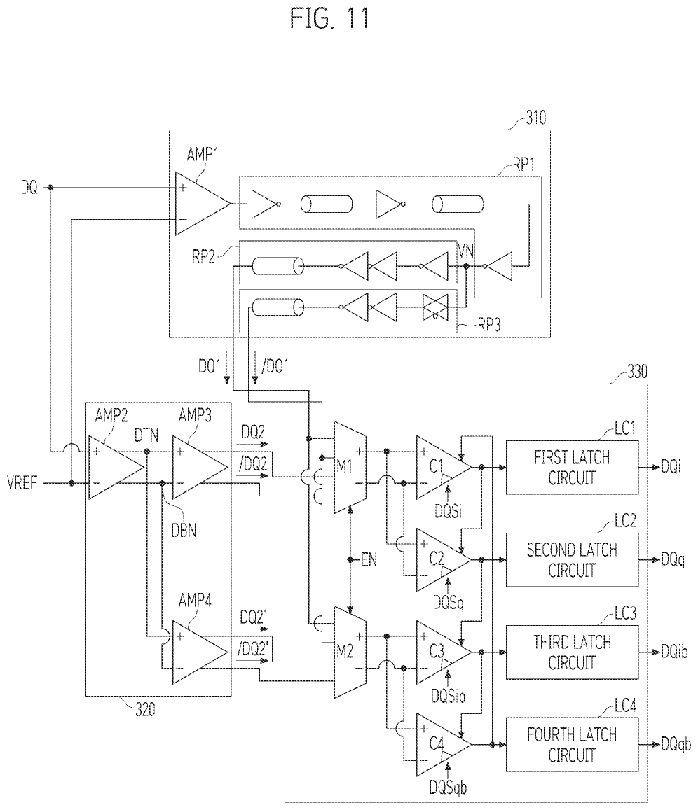

FIG. 11 is a block diagram illustrating another embodiment of the first data path 310, second data path 320, and synchronization path 330 illustrated in FIG. 8.

Referring to FIG. 11, the first data path 310 may include a first input circuit AMP1, a first replica circuit RP1, a second replica circuit RP2, and a third replica circuit RP3.

The first input circuit AMP1 may generate an input data signal on the basis of the data signal DQ and the reference signal VREF. For example, the first input circuit AMP1 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

The second replica circuit RP2 may delay the delayed input data signal by a second delay time amount and may generate a first positive data signal DQ1 among the first differential data signals DQ1 and/DQ1. For example, the second replica circuit RP2 may include one or more delay lines, for example, an RC line, and one or more repeaters. The one or more delay lines and the one or more repeaters may be coupled in series.

The third replica circuit RP3 may delay the delayed input data signal by the second delay time amount and may generate a first negative data signal/DQ1 among the first differential data signals DQ1 and/DQ1. For example, the third replica circuit RP3 may include one or more delay lines, for example, an RC line, and one or more repeaters. The one or more delay lines and the one or more repeaters may be coupled in series.

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 300 to a point in time when the first to fourth data strobe signals DQSi, DQSq, DQSib and DQSqb based on the data strobe signal are inputted to the synchronization path 330.

The second data path 320 may include second to fourth input circuits AMP2, AMP3 and AMP4.

The second input circuit AMP2 may output a differential input data signal to a pair of branch nodes DTN and DBN on the basis of the data signal DQ and the reference signal VREF. For example, the second input circuit AMP2 may include an amplifier.

The third input circuit AMP3 may generate the second differential data signals DQ2 and/DQ2 on the basis of the differential input data signal. For example, the third input circuit AMP3 may include an amplifier.

The fourth input circuit AMP4 may generate third differential data signal DQ2′ and/DQ2′ on the basis of the differential input data signal. For example, the fourth input circuit AMP4 may include an amplifier.

The second to fourth input circuits AMP2, AMP3 and AMP4 may be designed in the same manner as or differently from the second input circuit AMP2 illustrated in FIG. 4.

The synchronization path 330 may include first and second selection circuit M1 and M2, first to fourth comparison circuits C1 to C4, and first to fourth latch circuits LC1 to LC4.

The first selection circuit M1 may generate the first differential data signals DQ1 and/DQ1 or the second differential data signals DQ2 and/DQ2 as first differential selection data signals on the basis of the mode selection signal EN.

The second selection circuit M2 may generate the first differential data signals DQ1 and/DQ1 or the third differential data signals DQ2′ and/DQ2′ as second differential selection data signals on the basis of the mode selection signal EN.

The first comparison circuit C1 may be synchronized with the first data strobe signal DQSi and may perform a comparison operation for a first time amount. The first time amount may be related to a phase of the first data strobe signal DQSi. For example, the first time amount may correspond to one cycle of the first data strobe signal DQSi on the basis of a rising edge of the first data strobe signal DQSi. The first comparison circuit C1 may compare the first differential selection data signals with one another in the first mode and may generate and latch a first comparison data signal corresponding to a result of the comparing. The first comparison circuit C1 may compare the first differential selection data signals with one another in the second mode and may generate and latch the first comparison data signal corresponding to a result of the comparing.

The second comparison circuit C2 may be synchronized with the second data strobe signal DQSq and may perform the comparison operation for a second time amount. The second time amount may be related to a phase of the second data strobe signal DQSq. For example, the second time amount may correspond to one cycle of the second data strobe signal DQSq on the basis of a rising edge of the second data strobe signal DQSq. The second comparison circuit C2 may compare the first differential selection data signals with one another in the first mode and may generate and latch a second comparison data signal corresponding to a result of the comparing. The second comparison circuit C2 may compare the first differential selection data signals with one another in the second mode and may generate and latch the second comparison data signal corresponding to a result of the comparing.

The third comparison circuit C3 may be synchronized with the third data strobe signal DQSib and may perform the comparison operation for a third time amount. The third time amount may be related to a phase of the third data strobe signal DQSib. For example, the third time amount may correspond to one cycle of the third data strobe signal DQSib on the basis of a rising edge of the third data strobe signal DQSib. The third comparison circuit C3 may compare the second differential selection data signals with one another in the first mode and may generate and latch a third comparison data signal corresponding to a result of the comparing. The third comparison circuit C3 may compare the second differential selection data signals with one another in the second mode and may generate and latch the third comparison data signal corresponding to a result of the comparing.

The fourth comparison circuit C4 may be synchronized with the fourth data strobe signal DQSqb and may perform the comparison operation for a fourth time amount. The fourth time amount may be related to a phase of the fourth data strobe signal DQSqb. For example, the fourth time amount may correspond to one cycle of the fourth data strobe signal DQSqb on the basis of a rising edge of the fourth data strobe signal DQSqb. The fourth comparison circuit C4 may compare the second differential selection data signals with one another in the first mode and may generate and latch a fourth comparison data signal corresponding to a result of the comparing. The fourth comparison circuit C4 may compare the second differential selection data signals with one another in the second mode and may generate and latch the fourth comparison data signal corresponding to a result of the comparing.

Each of the first to fourth comparison circuits C₁ to C₄ may receive the comparison data signal outputted from the comparison circuit C₁ to C₄ adjacent thereto. The first comparison circuit C1 may receive the fourth comparison data signal outputted from the fourth comparison circuit C4. This operation is known as a decision feedback equalization (DFE) operation.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

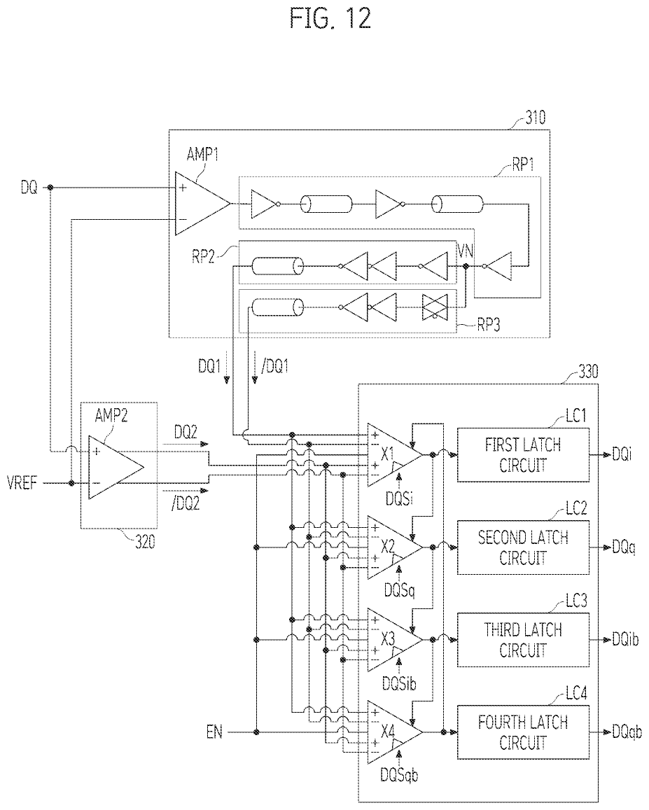

FIG. 12 is a block diagram illustrating another embodiment of the first data path 310, second data path 320, and synchronization path 330 illustrated in FIG. 8.

Referring to FIG. 12, the first data path 310 may include a first input circuit AMP1, a first replica circuit RP1, a second replica circuit RP2, and a third replica circuit RP3.

The first input circuit AMP1 may generate an input data signal on the basis of the data signal DQ and the reference signal VREF. For example, the first input circuit AMP1 may include an amplifier.

The first replica circuit RP1 may delay the input data signal by a first delay time amount and may output the delayed input data signal to a branch node VN. For example, the first replica circuit RP1 may include one or more delay lines, for example, an RC line, and one or more repeaters. The one or more delay lines and the one or more repeaters may be coupled in series.

The second replica circuit RP2 may delay the delayed input data signal by a second delay time amount and may generate a first positive data signal DQ1 among the first differential data signals DQ1 and/DQ1. For example, the second replica circuit RP2 may include one or more delay lines, for example, an RC line, and one or more repeaters. The one or more delay lines and the one or more repeaters may be coupled in series.

The third replica circuit RP3 may delay the delayed input data signal by the second delay time amount and may generate a first negative data signal/DQ1 among the first differential data signals DQ1 and/DQ1. For example, the third replica circuit RP3 may include one or more delay lines, for example, an RC line, and one or more repeaters. The one or more delay lines and the one or more repeaters may be coupled in series.

The first delay time amount and the second delay time amount may be determined according to the internal delay time amount caused by a path through which the first to fourth data strobe signals DQSi, DQSq, DQSib and DQSqb are transferred. For example, the sum of the first delay time amount and the second delay time amount may be equal to the internal delay time amount. Although not illustrated in the drawing, the internal delay time amount may include a point in time when a data strobe signal generated by the external device is inputted to a corresponding pad included in the semiconductor device 300 to a point in time when the first to fourth data strobe signals DQSi, DQSq, DQSib and DQSqb based on the data strobe signal are inputted to the synchronization path 330.

The second data path 320 may include a second input circuit AMP2.

The second input circuit AMP2 may generate the second differential data signals DQ2 and/DQ2 on the basis of the data signal DQ and the reference signal VREF. For example, the second input circuit AMP2 may include an amplifier.

The synchronization path 330 may include first to fourth integrated circuits X1 to X4, and first to fourth latch circuits LC1 to LC4.

The first integrated circuit X1 may select the first differential data signals DQ1 and/DQ1 or the second differential data signals DQ2 and/DQ2 for a first time amount and may simultaneously compare a positive data signal included in the selected differential data signals with a negative data signal included in the selected differential data signals, on the basis of the mode selection signal EN and the first data strobe signal DQSi and may consequently generate a first comparison data signal. The first time amount may be related to a phase of the first data strobe signal DQSi.

The second integrated circuit X2 may select the first differential data signals DQ1 and/DQ1 or the second differential data signals DQ2 and/DQ2 for a second time amount and may simultaneously compare a positive data signal included in the selected differential data signals with a negative data signal included in the selected differential data signals, on the basis of the mode selection signal EN and the second data strobe signal DQSq and may consequently generate a second comparison data signal. The second time amount may be related to a phase of the second data strobe signal DQSq.

The third integrated circuit X3 may select the first differential data signals DQ1 and/DQ1 or the second differential data signals DQ2 and/DQ2 for a third time amount and may simultaneously compare a positive data signal included in the selected differential data signals with a negative data signal included in the selected differential data signals, on the basis of the mode selection signal EN and the third data strobe signal DQSib and may consequently generate a third comparison data signal. The third time amount may be related to a phase of the third data strobe signal DQSib.

The fourth integrated circuit X4 may select the first differential data signals DQ1 and/DQ1 or the second differential data signals DQ2 and/DQ2 for a fourth time amount and may simultaneously compare a positive data signal included in the selected differential data signals with a negative data signal included in the selected differential data signals, on the basis of the mode selection signal EN and the fourth data strobe signal DQSqb and may consequently generate a fourth comparison data signal. The fourth time amount may be related to a phase of the fourth data strobe signal DQSqb.

The first latch circuit LC1 may latch the first comparison data signal as the first internal data signal DQi. For example, the first latch circuit LC1 may include an SR latch.

The second latch circuit LC2 may latch the second comparison data signal as the second internal data signal DQq. For example, the second latch circuit LC2 may include an SR latch.

The third latch circuit LC3 may latch the third comparison data signal as the third internal data signal DQib. For example, the third latch circuit LC3 may include an SR latch.

The fourth latch circuit LC4 may latch the fourth comparison data signal as the fourth internal data signal DQqb. For example, the fourth latch circuit LC4 may include an SR latch.

In an embodiment, it is described that the second data path 320 includes the second input circuit AMP2, but the embodiment is not necessarily limited thereto, and the second data path 320 may be designed in the same manner as the second data path 320 illustrated in FIG. 9. Accordingly, a coupling structure between the second data path 320 and the synchronization path 330 may be designed similarly to a coupling structure between the second data path 320 and synchronization path 330 illustrated in FIG. 9.

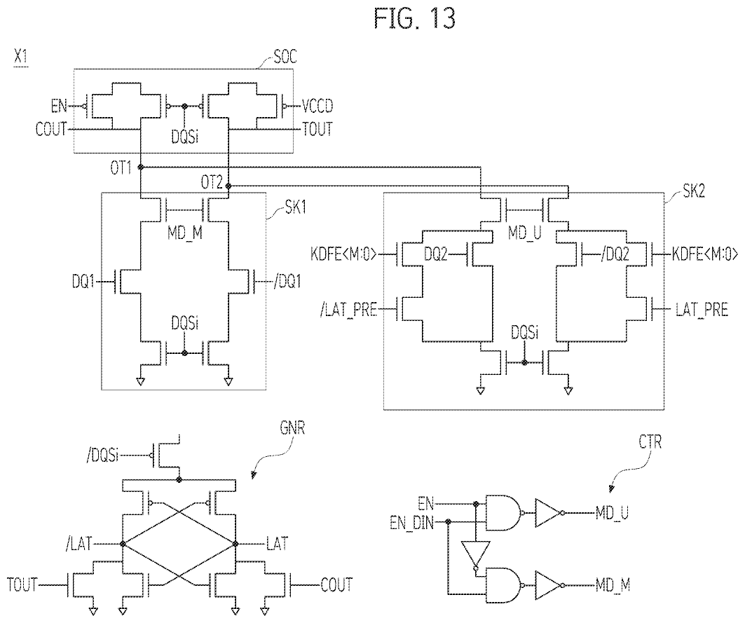

FIG. 13 is a circuit diagram illustrating the first integrated circuit X1 illustrated in FIG. 12. Since the first to fourth integrated circuits X1 to X4 may be designed in the same manner, the first integrated circuit X1 is representatively described below.

Referring to FIG. 13, the first integrated circuit X1 may include a common source circuit SOC, a first sink circuit SK1, and a second sink circuit SK2.

The common source circuit SOC may be coupled between a supply terminal of a first voltage and a pair of output terminals OT1 and OT2. The common source circuit SOC may reset or pre-charge the pair of output terminals OT1 and OT2 to the first voltage, for example, VDD, when the first data strobe signal DQSi is at a low logic level.

The first sink circuit SK1 may be coupled between the pair of output terminals OT1 and OT2 and a supply terminal of a second voltage. The first sink circuit SK1 may be enabled in the first mode, that is, the low-speed mode, and disabled in the second mode, that is, the high-speed mode, on the basis of a first mode signal MD_M. The first sink circuit SK1 may output differential data signals COUT and TOUT, which correspond to the first differential data signals DQ1 and/DQ1, through the pair of output terminals OT1 and OT2 on the basis of the first data strobe signal DQSi. The differential data signals COUT and TOUT may correspond to the result of comparing the positive data signal DQ1 with the negative data signal/DQ1 included in the first differential data signals DQ1 and/DQ1.

The second sink circuit SK2 may be coupled between the pair of output terminals OT1 and OT2 and the supply terminal of the second voltage. The second sink circuit SK2 may be enabled in the second mode and disabled in the first mode on the basis of a second mode signal MD_U. The second sink circuit SK2 may output the differential data signals COUT and TOUT, which correspond to the second differential data signals DQ2 and/DQ2, through the pair of output terminals OT1 and OT2 on the basis of the first data strobe signal DQSi. The differential data signals COUT and TOUT may correspond to the result of comparing the positive data signal DQ2 with the negative data signal/DQ2 included in the second differential data signals DQ2 and/DQ2. When the differential data signals COUT and TOUT are generated, the second sink circuit SK2 may perform a decision feedback equalization (DFE) operation on the basis of an equalization control signal KDFE<M: 0> and previous differential data signals LAT_PRE and/LAT_PRE.

A generation circuit GNR may generate differential comparison data signals LAT and/LAT on the basis of the differential data signals COUT and TOUT. One of a positive comparison data signal LAT and a negative comparison data signal/LAT included in the differential comparison data signals LAT and/LAT may be the first comparison data signal.

In an embodiment, the common source circuit SOC, the first sink circuit SK1, the second sink circuit SK2 and the generation circuit GNR may be configurations in which a double-tail latch-based comparison circuit and a circuit for the DFE are integrated. However, the embodiment is not necessarily limited to this, and may have a configuration in which various types of comparison circuits, for example, a strong-arm-based comparison circuit, and the circuit for the DFE are integrated.

A control circuit CTR may generate the first mode signal MD_M and the second mode signal MD_U on the basis of the mode selection signal EN and an operation enable signal EN_DIN. For example, the control circuit CTR may activate the first mode signal MD_M and deactivate the second mode signal MD_U in the first mode, may deactivate the first mode signal MD_M and activate the second mode signal MD_U in the second mode, and may deactivate both of the first mode signal MD_M and the second mode signal MD_U in a specific mode. The operation enable signal EN_DIN may be a write enable signal corresponding to a write mode, and the specific mode may be at least one mode excluding the write mode.

In an embodiment, it is described that the control circuit CTR is included in each of the first to fourth integrated circuits X1 to X4, but the embodiment is not necessarily limited thereto, and the first to fourth integrated circuits X1 to X4 may be designed to share one control circuit CTR.

According to embodiments of the present disclosure, various interface modes may be supported.

According to embodiments of the present disclosure, various interface modes may be supported, thereby improving compatibility.

While the present disclosure has been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. Therefore, the scope of the present disclosure should not be limited to the above-described embodiments but should include the equivalents thereof.

In the above-described embodiments, all operations may be selectively performed, or part of the operations may be omitted. In each embodiment, the operations are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

The embodiments of the present disclosure have been described in the drawings and specification. Although specific terminologies are used here, those are only to describe the embodiments of the present disclosure. Therefore, the present disclosure is not restricted to the above-described embodiments and many variations are possible within the scope of the present disclosure. It should be apparent to those skilled in the art that various modifications can be made on the basis of the technological scope of the present disclosure in addition to the embodiments disclosed herein. Furthermore, the embodiments may be combined to form additional embodiments.

What is claimed is:

1. A semiconductor device comprising:
a data pad;
at least one merge node;
a first data path coupled between the data pad and the at least one merge node and suitable for outputting, in a first mode, a first data signal to the at least one merge node based on a data signal, a reference signal and a mode selection signal;
a second data path coupled between the data pad and the at least one merge node and suitable for outputting, in a second mode, a second data signal to the at least one merge node based on the data signal, the reference signal and the mode selection signal; and
a synchronization path coupled to the at least one merge node and suitable for outputting, in one of the first and second modes, a corresponding signal of the first and second data signals as a data signal synchronized with at least one data strobe signal.

2. The semiconductor device of claim 1,
wherein the at least one merge node includes first and second merge nodes, and
wherein the first data path includes:
a first input circuit suitable for generating an input data signal based on the data signal and the reference signal;
a first replica circuit suitable for delaying the input data signal by a first delay time amount and outputting the delayed input data signal to a branch node;
a second replica circuit suitable for delaying the delayed input data signal by a second delay time amount and outputting, to the first merge node, a first positive data signal corresponding to the first data signal; and
a third replica circuit suitable for delaying the delayed input data signal by the second delay time amount and outputting, to the second merge node, a first negative data signal corresponding to the first data signal.

3. The semiconductor device of claim 2, wherein the second replica circuit includes:
a first pull-up driver coupled between a supply terminal of a first voltage and a first supply node and suitable for receiving a first driving data signal corresponding to the delayed input data signal;
a first selection driver coupled between the first supply node and a first output node and suitable for receiving the mode selection signal;
a second selection driver coupled between the first output node and a second supply node and suitable for receiving an inversion signal of the mode selection signal; and
a first pull-down driver coupled between the second supply node and a supply terminal of a second voltage and suitable for receiving the first driving data signal.

4. The semiconductor device of claim 2, wherein the third replica circuit includes:
a second pull-up driver coupled between a supply terminal of a first voltage and a third supply node and suitable for receiving a second driving data signal corresponding to the delayed input data signal;
a third selection driver coupled between the third supply node and a second output node and suitable for receiving the mode selection signal;
a fourth selection driver coupled between the second output node and a fourth supply node and suitable for receiving an inversion signal of the mode selection signal; and
a second pull-down driver coupled between the fourth supply node and a supply terminal of a second voltage and suitable for receiving the second driving data signal.

5. The semiconductor device of claim 2, wherein the first delay time amount and the second delay time amount are determined according to an internal delay time amount caused by a path through which the data strobe signal is transferred.

6. The semiconductor device of claim 2, wherein the second data path includes a second input circuit suitable for outputting, to the respective first and second merge nodes, a second positive data signal and a second negative data signal, which correspond to the second data signal, based on the data signal and the reference signal.

7. The semiconductor device of claim 6, wherein the second input circuit includes:
a source driver coupled between a supply terminal of a first voltage and a common node and suitable for receiving a bias voltage;
a first input driver coupled between the common node and a first node and suitable for receiving the data signal;
a fifth selection driver coupled between the first node and the second merge node and suitable for receiving an inversion signal of the mode selection signal;
a second input driver coupled between the common node and a second node and suitable for receiving the reference signal;
a sixth selection driver coupled between the second node and the first merge node and suitable for receiving the inversion signal of the mode selection signal;
a first sink driver coupled between the second merge node and a supply terminal of a second voltage and suitable for receiving a control signal;
a second sink driver coupled between the first merge node and the supply terminal of the second voltage and suitable for receiving the control signal; and
a logic circuit suitable for generating the control signal based on the mode selection signal and an enable signal.

8. The semiconductor device of claim 6, wherein the synchronization path includes:
at least one comparison circuit suitable for generating, based on the at least one data strobe signal, at least one comparison data signal by comparing first and second target signals with each other, the first target signal being one of the first and second positive data signals, which are outputted through the first merge node, and the second target signal being one of the first and second negative data signals, which are outputted through the second merge node; and
at least one latch circuit suitable for latching the at least one comparison data signal as the data signal synchronized with the at least one data strobe signal.

9. The semiconductor device of claim 8, wherein the at least one comparison circuit performs the comparing through a decision feedback equalization (DFE) operation.

10. The semiconductor device of claim 1,
wherein the at least one merge node includes first to fourth merge nodes, and
wherein the first data path includes:
a first input circuit suitable for generating an input data signal based on the data signal and the reference signal;
a first replica circuit suitable for delaying the input data signal by a first delay time amount and outputting the delayed input data signal to a branch node;
a second replica circuit suitable for delaying the delayed input data signal by a second delay time amount and outputting, to the first and third merge nodes, a first positive data signal corresponding to the first data signal; and
a third replica circuit suitable for delaying the delayed input data signal by the second delay time amount and outputting, to the second and fourth merge nodes, a first negative data signal corresponding to the first data signal.

11. The semiconductor device of claim 10, wherein the second data path includes:
a second input circuit suitable for outputting, to respective first and second nodes, a positive input data signal and a negative input data signal based on the data signal and the reference signal;
a first amplification circuit suitable for outputting, to the respective first and second merge nodes, a second positive data signal and a second negative data signal, which correspond to the second data signal, based on the positive input data signal and the negative input data signal; and
a second amplification circuit suitable for outputting, to the respective third and fourth merge nodes, a third positive data signal and a third negative data signal, which correspond to the second data signal, based on the positive input data signal and the negative input data signal.

12. The semiconductor device of claim 11, wherein the synchronization path includes:
at least one first comparison circuit suitable for generating, based on the at least one data strobe signal, at least one first comparison data signal by comparing first and second target signals with each other, the first target signal being one of the first and second positive data signals, which are outputted through the first merge node, and the second target signal being one of the first and second negative data signal, which are outputted through the second merge node;
at least one second comparison circuit suitable for generating, based on the at least one data strobe signal, at least one second comparison data signal by comparing third and fourth target signals with each other, the third target signal being one of the first and second positive data signals, which are outputted through the third merge node, and the fourth target signal being one of the first and second negative data signals, which are outputted through the fourth merge node; and
a plurality of latch circuits suitable for latching the at least one first comparison data signal and the at least one second comparison data signal as the data signal synchronized with the at least one data strobe signal.

13. The semiconductor device of claim 12, wherein each of the at least one first comparison circuit and the at least one second comparison circuit performs the comparing through a decision feedback equalization (DFE) operation.

14. A semiconductor device comprising:
a data pad;
at least one common node;
a common path coupled between the data pad and the at least one common node and suitable for outputting a common data signal to the at least one common node based on a data signal and a reference signal;
at least one merge node;
a first data path coupled between the at least one common node and the at least one merge node and suitable for outputting, in a first mode, a first data signal to the at least one merge node based on the common data signal and a mode selection signal;
a second data path coupled between the at least one common node and the at least one merge node and suitable for outputting, in a second mode, a second data signal to the at least one merge node based on the common data signal and the mode selection signal; and
a synchronization path coupled to the at least one merge node and suitable for outputting, in one of the first and second modes, a corresponding signal of the first and second data signals as a data signal synchronized with a data strobe signal.

15. The semiconductor device of claim 14,
wherein the at least one merge node includes first and second merge nodes, and
wherein the first data path includes:
a first input circuit suitable for generating an input data signal based on the common data signal and the mode selection signal;
a first replica circuit suitable for delaying the input data signal by a first delay time amount and outputting the delayed input data signal to a branch node;
a second replica circuit suitable for delaying the delayed input data signal by a second delay time amount and outputting, to the first merge node, a first positive data signal corresponding to the first data signal; and
a third replica circuit suitable for delaying the delayed input data signal by the second delay time amount and outputting, to the second merge node, a first negative data signal corresponding to the first data signal.

16. The semiconductor device of claim 15, wherein the second replica circuit includes:
a first pull-up driver coupled between a supply terminal of a first voltage and a first supply node and suitable for receiving a first driving data signal corresponding to the delayed input data signal;
a first selection driver coupled between the first supply node and a first output node and suitable for receiving the mode selection signal;
a second selection driver coupled between the first output node and a second supply node and suitable for receiving an inversion signal of the mode selection signal; and
a first pull-down driver coupled between the second supply node and a supply terminal of a second voltage and suitable for receiving the first driving data signal.

17. The semiconductor device of claim 15, wherein the third replica circuit includes:
a second pull-up driver coupled between a supply terminal of a first voltage and a third supply node and suitable for receiving a second driving data signal corresponding to the delayed input data signal;
a third selection driver coupled between the third supply node and a second output node and suitable for receiving the mode selection signal;
a fourth selection driver coupled between the second output node and a fourth supply node and suitable for receiving an inversion signal of the mode selection signal; and
a second pull-down driver coupled between the fourth supply node and a supply terminal of a second voltage and suitable for receiving the second driving data signal.

18. The semiconductor device of claim 15, wherein the first delay time amount and the second delay time amount are determined according to an internal delay time amount caused by a path through which the data strobe signal is transferred.

19. The semiconductor device of claim 15, wherein the second data path includes a second input circuit suitable for outputting, to the respective first and second merge nodes, a second positive data signal and a second negative data signal, which correspond to the second data signal, based on the common data signal and the mode selection signal.

20. The semiconductor device of claim 19, wherein the second input circuit includes:
a source driver coupled between a supply terminal of a first voltage and a common node and suitable for receiving a bias voltage;
a first input driver coupled between the common node and a first node and suitable for receiving a positive data signal among differential data signals corresponding to the common data signal;
a fifth selection driver coupled between the first node and the second merge node and suitable for receiving an inversion signal of the mode selection signal;
a second input driver coupled between the common node and a second node and suitable for receiving a negative data signal among the differential data signals;
a sixth selection driver coupled between the second node and the first merge node and suitable for receiving the inversion signal of the mode selection signal;
a first sink driver coupled between the second merge node and a supply terminal of a second voltage and suitable for receiving a control signal;
a second sink driver coupled between the first merge node and the supply terminal of the second voltage and suitable for receiving the control signal; and
a logic circuit suitable for generating the control signal based on the mode selection signal and an enable signal.

21. The semiconductor device of claim 19, wherein the synchronization path includes:
at least one comparison circuit suitable for generating, based on the at least one data strobe signal, at least one comparison data signal by comparing first and second target signals with each other, the first target signal being one of the first and second positive data signals, which are outputted through the first merge node, and the second target signal being one of the first and second negative data signals, which are outputted through the second merge node; and
at least one latch circuit suitable for latching the at least one comparison data signal as the data signal synchronized with the data strobe signal.

22. The semiconductor device of claim 21, wherein the at least one comparison circuit performs the comparing through a decision feedback equalization (DFE) operation.

23. A semiconductor device comprising:
a first data path suitable for generating, in a first mode, a first data signal based on a data signal and a reference signal;
a second data path suitable for generating, in a second mode, a second data signal based on the data signal and the reference signal; and
a synchronization path suitable for outputting, in each of the first and second modes, a selected signal from among the first and second data signals as a data signal synchronized with at least one data strobe signal based on a mode selection signal, the at least one data strobe signal and the first and second data signals.

24. The semiconductor device of claim 23, wherein the first data path includes:
a first input circuit suitable for generating an input data signal based on the data signal and the reference signal;
a first replica circuit suitable for delaying the input data signal by a first delay time amount and outputting the delayed input data signal to a branch node;
a second replica circuit suitable for delaying the delayed input data signal by a second delay time amount and generating a first positive data signal corresponding to the first data signal; and
a third replica circuit suitable for delaying the delayed input data signal by the second delay time amount and generating a first negative data signal corresponding to the first data signal.

25. The semiconductor device of claim 24, wherein the first delay time amount and the second delay time amount are determined according to an internal delay time amount caused by a path through which the at least one data strobe signal is transferred.

26. The semiconductor device of claim 23, wherein the second data path includes:
a second input circuit suitable for generating an input data signal based on the data signal and the reference signal;
a first amplification circuit suitable for generating a third data signal, which corresponds to the second data signal, based on the input data signal;
a second amplification circuit suitable for generating a fourth data signal, which corresponds to the second data signal, based on the input data signal.

27. The semiconductor device of claim 26, wherein the synchronization path includes:
a first selection circuit suitable for outputting, as a first selection data signal, one of the first data signal and the third data signal based on the mode selection signal;
at least one first comparison circuit suitable for generating, based on the at least one data strobe signal, at least one first comparison data signal by comparing a positive signal and a negative signal, which are included in the first selection data signal;
a second selection circuit suitable for outputting, as a second selection data signal, one of the first data signal and the fourth data signal based on the mode selection signal;
at least one second comparison circuit suitable for generating, based on the at least one data strobe signal, at least one second comparison data signal by comparing a positive signal and a negative signal, which are included in the second selection data signal; and
a plurality of latch circuits suitable for latching the at least one first comparison data signal and the at least one second comparison data signal as the data signal synchronized with the at least one data strobe signal.

28. The semiconductor device of claim 27, wherein each of the at least one first comparison circuit and the at least one second comparison circuit performs the comparing through a decision feedback equalization (DFE) operation.

29. The semiconductor device of claim 23, wherein the synchronization path includes:
at least one integrated circuit suitable for selecting one of the first data signal and the second data signal and generating at least one comparison data signal by comparing a positive signal and a negative signal, which are included in the selected data signal, based on the mode selection signal and the at least one data strobe signal; and
at least one latch circuit suitable for latching the at least one comparison data signal as the data signal synchronized with the at least one data strobe signal.

30. The semiconductor device of claim 29, wherein the at least one integrated circuit includes:
a common source circuit coupled between a supply terminal of a first voltage and a pair of output nodes;
a first sink circuit coupled between the pair of output nodes and a supply terminal of a second voltage, and suitable for outputting, in a first mode, a differential data signal corresponding to the first data signal through the pair of output nodes based on the at least one data strobe signal;
a second sink circuit coupled between the pair of output nodes and the supply terminal of the second voltage and suitable for outputting, in a second mode, a differential data signal corresponding to the second data signal through the pair of output nodes based on the at least one data strobe signal; and
a generation circuit suitable for generating the at least one comparison data signal based on the differential data signal corresponding to the selected signal of the first and second data signals.

31. The semiconductor device of claim 30, wherein the second sink circuit is further suitable for generating the differential data signal corresponding to the second data signal by performing a decision feedback equalization (DFE) operation based on at least one equalization control signal and a previous differential data signal.

32. The semiconductor device of claim 30, wherein at least one integrated circuit further includes a control circuit suitable for activating each of the first and second modes based on the mode selection signal and an operation enable signal.
